(19) United States
(12) Patent Application Publication
(10) Pub. No.: US 2025/0066899 A1
(43) Pub. Date: Feb. 27, 2025

(54) METHOD OF PHYSICAL VAPOR DEPOSITION WITH INTERMIXING REDUCTION

(71) Applicant: Taiwan Semiconductor Manufacturing Co., Ltd., Hsinchu (TW)

(72) Inventors: Chun-Yen LIAO, Hsinchu (TW); I. LEE, Hsinchu (TW); Shu-Lan CHANG, Hsinchu (TW); Sheng-Hsuan LIN, Hsinchu (TW); Feng-Yu CHANG, Hsinchu (TW); Wei-Jung LIN, Hsinchu (TW); Chun-I TSAI, Hsinchu (TW); Chih-Chien CHI, Hsinchu (TW); Ming-Hsing TSAI, Hsinchu (TW); Pei Shan CHANG, Hsinchu (TW); Chih-Wei CHANG, Hsinchu (TW)

(21) Appl. No.: 18/454,702

(22) Filed: Aug. 23, 2023

(51) Int. Cl. C23C 14/04; C23C 14/34; C23C 14/50; C23C 14/54; C23C 14/58

(52) U.S. Cl. CPC C23C 14/046; C23C 14/3407; C23C 14/50; C23C 14/541; C23C 14/58

(57) ABSTRACT

A method includes: positioning a wafer on an electrostatic chuck of a physical vapor deposition apparatus, the wafer including an opening exposing a conductive feature; setting a temperature of the wafer to a room temperature; forming a tungsten thin film in the opening by the physical vapor deposition apparatus, the tungsten thin film including a bottom portion that is on an upper surface of the conductive feature exposed by the opening, a top portion that is on an upper surface of a dielectric layer through which the opening extends and a sidewall portion that is on a sidewall of the dielectric layer exposed by the opening; removing the top portion and the sidewall portion of the tungsten thin film from over the opening; and forming a tungsten plug in the opening on the bottom portion by selectively depositing tungsten by a chemical vapor deposition operation.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing ICs.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A and 1B are views of a deposition apparatus according to embodiments of the present disclosure.

FIGS. 2A-2C are views of a semiconductor device according to various aspects of the present disclosure.

FIG. 3A-3D are views illustrating a process for forming a conductive feature according to various aspects of the present disclosure.

FIG. 4 is a diagrammatic cross-sectional view of a semiconductor device where a conductive feature formed by the example method of FIGS. 3A-3D may be utilized in accordance with some embodiments.

FIG. 5 is a flow chart of a semiconductor processing method according to various aspects of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Terms such as “about,” “roughly,” “substantially,” and the like may be used herein for ease of description. A person having ordinary skill in the art will be able to understand and derive meanings for such terms. For example, “about” may indicate variation in a dimension of 20%, 10%, 5% or the like, but other values may be used when appropriate. A large feature, such as the longest dimension of a semiconductor fin may have variation less than 5%, whereas a very small feature, such as thickness of an interfacial layer may have variation of as much as 50%, and both types of variation may be represented by the term “about.” “Substantially” is generally more stringent than “about,” such that variation of 10%, 5% or less may be appropriate, without limit thereto. A feature that is “substantially planar” may have variation from a straight line that is within 10% or less. A material with a “substantially constant concentration” may have variation of concentration along one or more dimensions that is within 5% or less. Again, a person having ordinary skill in the art will be able to understand and derive appropriate meanings for such terms based on knowledge of the industry, current fabrication techniques, and the like.

Semiconductor fabrication generally involves the formation of electronic circuits by performing multiple depositions, etchings, annealings and/or implantations of material layers, whereby a stack structure including many semiconductor devices and interconnects between is formed. Dimension scaling (down) is one technique employed to fit ever greater numbers of semiconductor devices in the same area. However, dimension scaling is increasingly difficult in advanced technology nodes. Deposition techniques encounter ever more stringent layer deposition uniformity specifications, while layer thicknesses decrease to form smaller features.

A target for PVD generally includes a deposition material layer attached to a base plate, for example, by an adhesion layer including a metal, such as indium. Material of the target is deposited as a thin layer onto a wafer held in place by a wafer support, such as an electrostatic chuck. PVD deposition apparatuses with poor bottom coverage capability deposit an insufficient amount of metal, such as tungsten, at a contact bottom, which causes high resistance that can be detected by wafer acceptance test (WAT). PVD deposition apparatuses employ a high temperature when depositing tungsten, which the inventors have realized results in significant tungsten intermixing with an underlayer (e.g., layer on which tungsten is deposited), which induces selective loss in subsequent selective tungsten deposition and causes yield issues. To obtain sufficient bottom tungsten thickness, more tungsten may be deposited on both top and bottom. However, this approach increases loading of a subsequent process that removes the topside tungsten. A top opening may also shrink due to overhang of the topside tungsten, which reduces process window of subsequent processes.

Embodiments of the disclosure include PVD continuous-in-process (CIP) deposition apparatuses with improved bottom coverage and lower intermixing level with the underlayer, which is beneficial to achieve improved wafer acceptance test (WAT) and/or yield performance. A higher RF power is applied to increase W-ion generation and improved W-ion directionality is achieved by longer spacing, which are both beneficial to achieving improved bottom coverage without top material increase and opening degradation due to overhang. A low temperature is used for the wafer, which reduces intermixing of tungsten with the underlayer, which is beneficial to WAT and yield. A thicker bottom layer is associated with reduced contact resistance, which may be due to larger grain or a greater proportion of a contact being formed by a pure PVD process.

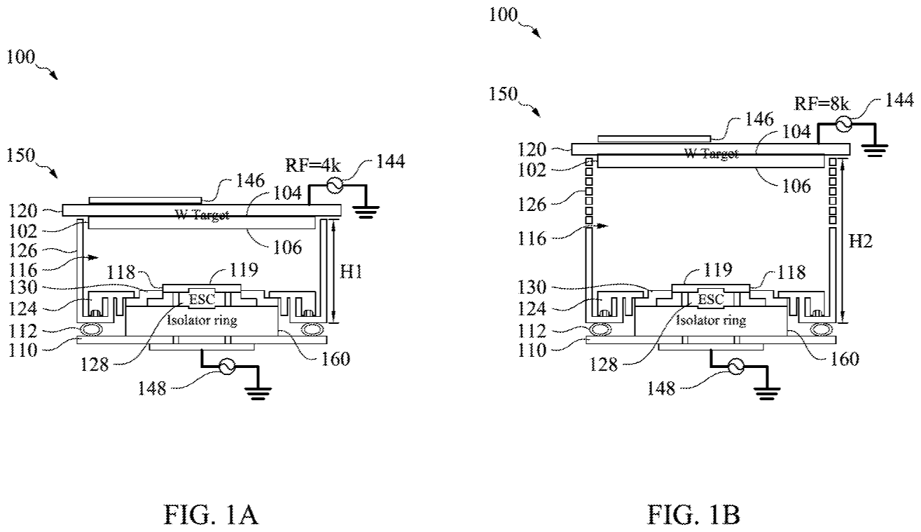

FIGS. 1A and 1B illustrate an example treatment chamber or deposition apparatus 100 in which a second layer may be formed on a first layer using a suitable deposition process such as physical vapor deposition (PVD). In some embodiments, the treatment chamber 100 comprises a grounding strip 112, a grounding bracket 110, a wafer support or electrostatic chuck 128 comprising a bottom electrode (not illustrated), a first shield 126, a second shield (not illustrated), a target 102, and a top electrode 120 above the target 102. In some embodiments, the target 102 comprises tungsten. The substrate 118 is disposed on the electrostatic chuck 128 with a layer thereof exposed on its top surface. The electrostatic chuck 128 may be separated and physically isolated from the grounding bracket 110 by an isolator ring 160.

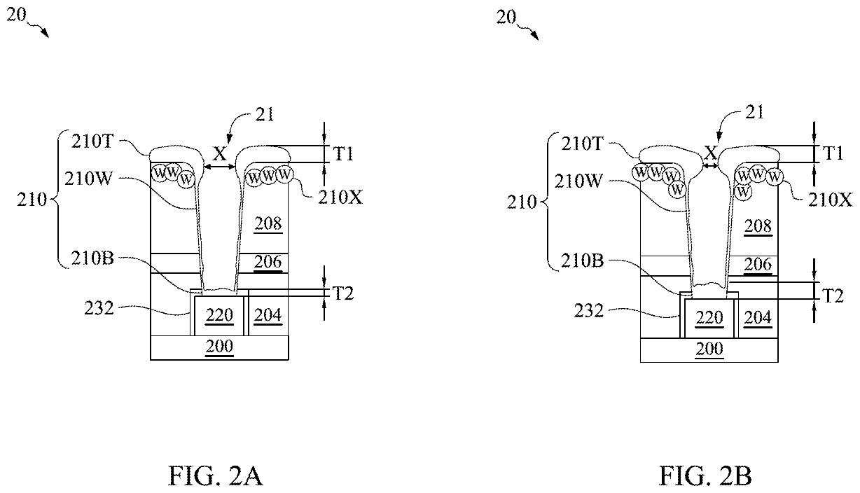

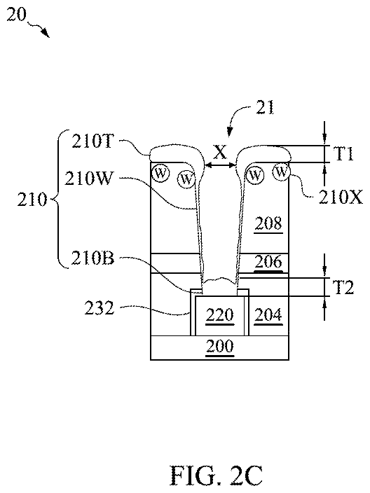

The deposition apparatus 100 may also be referred to as “PVD system 100” according to some embodiments. The deposition apparatus 100 is a PVD apparatus or system, in some embodiments. The views depicted in FIGS. 1A and 1B are cross-sectional views to illustrate internal features of the PVD system 100. In FIG. 1A, the PVD system 100 includes a PVD chamber 150 (or, “process chamber 150”) having a PVD volume 116 in which a target material (or, “deposition material layer”) of a target 102 may be deposited onto a wafer 118. In some embodiments, the PVD system 100 performs a PVD process to form a thin film on a surface 119 of the wafer 118, such as for fabrication of one or more semiconductor devices. The thin film comprises the target material. In some embodiments, the thin film is at least one of a bottom conductive contact layer 210B (depicted in FIGS. 2A-2C) or other suitable thin film.

The wafer support 128 of the PVD system 100 is in the PVD chamber 150. The wafer support 128 is configured to support the wafer 118 in the PVD volume 116. The wafer support 128 comprises at least one of a wafer chuck, an electrostatic chuck, a pedestal, or other suitable structure. In some embodiments, the wafer support 128 comprises a heater configured to heat the wafer 118, such as during performance of the PVD process. In embodiments of the present disclosure, the heater may be optional, may be turned off or may be set to maintain the wafer 118 at a temperature at or around room or ambient temperature, such as about 15 degrees Celsius to about 30 degrees Celsius, such as about 20 degrees Celsius to about 25 degrees Celsius in one example.

The top electrode or “backplane structure” 120 (or “base plate 120”) of the PVD system 100 overlies the target 102. The target 102 is coupled to at least one of the backplane structure 120 or other portion of the PVD chamber 150 to maintain a position of the target 102 between the backplane structure 120 and the wafer 118. Other structures and/or configurations of the backplane structure 120, the target 102, and/or the PVD chamber 150 are within the scope of the present disclosure. In some embodiments, the backplane structure 120 is or comprises copper, aluminum, molybdenum, an alloy of any of the above, or other suitable material.

The PVD system 100 comprises at least one of a cover structure 124 (such as a cover ring), a shielding structure 126 or a deposition structure 130 (such as a deposition ring). The shielding structure 126 is configured to inhibit dissipation of a gas from the PVD volume 116. The PVD chamber 150 comprises an inner chamber wall underlying the backplane structure 120. In some embodiments, the gas is conducted into the PVD volume 116 via a path between the cover structure 124 and the shielding structure 126. Other structures and/or configurations of the cover structure 124, the shielding structure 126, the inner chamber wall and/or the deposition structure 130 are within the scope of the present disclosure.

The target 102 comprises at least one of tungsten (W), titanium (Ti), aluminum (Al), titanium nitride (TiN), titanium aluminum (TiAl), copper (Cu), cobalt (Co), aluminum copper (AlCu), copper aluminum (CuAl), copper manganese (CuMn), tantalum (Ta), or other suitable material. In most embodiments of the present disclosure, the target 102 is described in terms of being tungsten. The target 102 overlies the wafer 118. A first surface 104 of the target 102 at least one of underlies, is in direct contact with, or is in indirect contact with the backplane structure 120. A second surface 106 of the target 102 faces the wafer 118. The target 102 may have vertical sidewalls as shown or tapered sidewalls. Other structures and/or configurations of the target 102 are within the scope of the present disclosure.

The PVD system 100 comprises a first power generator 144 electrically coupled to the PVD chamber 150, such as to the backplane structure 120 or other portion of the PVD chamber 150. The first power generator 144 is configured to generate a power, such as at least one of a radio frequency (RF) power or a direct current (DC) power. The PVD system 100 comprises one or more magnets 146. In some embodiments, the PVD system 100 comprises a second power generator 148 electrically coupled to the PVD chamber 150, such as to the wafer support 128 or other portion of the PVD chamber 150. The second power generator is configured to generate a bias power. The PVD system 100 is configured to establish a plasma in the PVD volume 116 from the gas. The plasma is used for depositing the target material of the target 102 onto the wafer 118, such as to form the bottom conductive contact layer 210B on the surface 119 of the wafer 118. The target material (such as atoms and/or molecules of the target 102) is dislodged from the target 102 and converted into vapor by the plasma (such as by means of gaseous ions of the plasma bombarding and/or impinging upon the target 102). The vapor undergoes condensation on the wafer 118, such as to form the thin film on the surface 119 of the wafer 118. The PVD system 100 establishes the plasma using at least one of the first power generator 144, the second power generator 148, the one or more magnets 146, or one or more other suitable components of the PVD system 100. At least one of the first power generator 144, the second power generator 148 or the one or more magnets 146 are controlled to at least one of control an ion bombardment force in the PVD volume 116 or to obtain one or more desired properties of the thin film formed on the surface 119 of the wafer 118. Interactions among the first power generator 144, the second power generator 148, the one or more magnets 146 and/or the wafer support 128 are within the scope of the present disclosure.

With reference to FIG. 1A and FIGS. 2A and 2B, material of the target 102 may be deposited as a thin layer 210 onto a semiconductor device 20 (see FIG. 2A) having an opening 21 that exposes a feature 220 to which electrical contact is to be made. For example, the feature 220 may be a gate structure, such as a high-k metal gate, a source/drain region or silicide thereof, a metal wire or trace, or the like. The feature 220 may be positioned on a substrate 200, which may be a semiconductor fin. The feature 220 may be covered by a barrier layer or etch stop layer (ESL) 232. The opening 21 may extend through a first dielectric layer 204, an etch stop layer 206, a second dielectric layer 208 and the barrier layer 232 to expose an upper surface of the feature 220. In some embodiments, the etch stop layer 206 and the second dielectric layer 208 are not present. The first and second dielectric layers 204, 208 may be interlayer dielectric layers (ILDs), and may be or include silicon dioxide, carbon doped silicon dioxide, silicon oxynitride, borosilicate glass (BSG), phosphoric silicate glass (PSG), borophosphosilicate glass (BPSG), fluorinated silicate glass (FSG), a porous dielectric material, or the like. The ESLs 206, 232 may be or include silicon nitride, silicon carbo-nitride, or the like.

As depicted in FIG. 2A, an initial metal layer 210, such as a tungsten thin film, may be deposited in the opening 21 and on top surfaces of a layer 208 that the opening 21 extends through by the PVD system 100 depicted in FIG. 1A. The tungsten thin film 210 includes a top portion 210T, sidewall portion 210W and bottom portion 210B (i.e., the bottom conductive contact layer 210B). The top portion 210T is on the upper surface of the layer 208. The sidewall portion 210W is on a sidewall(s) of the layer 208, a layer 206 and a layer 204 exposed by the opening 21. The bottom portion 210B is on an upper surface of the feature 220. Deposition of the tungsten thin film 210 may be performed such that the tungsten thin film 210 is deposited to a selected thickness T1, such as about 50 Angstroms (A). For example, the top portion 210T may have thickness equal to the selected thickness T1. However, bottom thickness T2 of the bottom portion 210B of the tungsten thin film 210 on the upper surface of the feature 220 may be much less than the selected thickness T1. For example, the bottom thickness T2 of the bottom portion 210B may be about 20A instead of the selected thickness T2 of 50 A. The inventors have realized that insufficient amount of metal, such as tungsten, at the bottom portion 210T is associated with increased contact resistance, which is detrimental to circuit performance.

The selected thickness T2 may be controlled by selection of RF power of the first power generator 144 and duration of a deposition operation. For example, the RF power may be selected to be less than about 4 kilowatts (kW). RF power below about 4 kW may be associated with a lower rate of tungsten ionization that increases overhang of the top portion 210T, which degrades tungsten coverage. Fewer tungsten ions being generated due to lower tungsten ionization increases the chance of ion bombardment on the top portion 210T and creates overhang of the top portion 210T and thereby reduces the width X of the opening 21.

To improve adhesion of the tungsten thin film 210 to the feature 220, the wafer 118 may be heated by the heater to a temperature significantly above ambient or room temperature, such as to about 400 degrees Celsius. However, the relatively high temperature of the wafer 118 causes significant intermixing of tungsten 210X with the layer 208, which is depicted in FIG. 2A. The tungsten 210X at the upper surface of the layer 208 may lead to reduced selectivity during a subsequent deposition of tungsten that is intended to fill (entirely or partially) the opening 21 on top of the bottom conductive contact layer 210B.

The target 102 may be separated from the wafer 118 by a distance H1 depicted in FIG. 1A. The height H1 may be less than about 100 millimeters (mm), such as about 95 mm. A shorter height H1 is associated with lower tungsten ion directionality control, which may contribute to overhang of a top portion 210T of the tungsten thin film 210. As such, width X of the opening 21 may be reduced due to the overhang of the top portion 210T, as depicted in FIG. 2A. For example, the width X may be in a range of about 5 nanometers (nm) to about 40 nm. Reduced width X of the opening 21 is associated with causing smaller process window for subsequent processes.

In FIG. 2B, the tungsten thin film 210 is deposited with similar parameters but may have a longer deposition duration so as to increase the bottom thickness T2 of the bottom portion 210B. For example, instead of depositing the tungsten thin film 210 to the selected thickness T1 of about 50A, the tungsten thin film 210 may be deposited to the selected thickness T1 of about 75A, resulting in the bottom portion 210B having the bottom thickness T2 of about 30A. However, due to the increased duration of the deposition operation, the overhang of the top portion 210T may be increased, such that the width X is decreased significantly, as depicted in FIG. 2B. For example, the width X of the opening 21 may be less than about 5 nm, which reduces process window for subsequent operations.

In FIG. 1B and FIG. 2C, the PVD system 100 depicted in FIG. 1B includes differences in structure of the PVD system 100 and operation thereof compared to FIG. 1A that improve deposition of the tungsten thin film 210 depicted in FIG. 2C.

In the PVD system 100 of FIG. 1B, the electrostatic chuck 118 is operated at room temperature (e.g., about 15 degrees Celsius to about 30 degrees Celsius) instead of at a high temperature (e.g., above about 100 degrees Celsius, such as 400 degrees Celsius). Performing deposition of the tungsten thin film 210 while the wafer 119 is at room temperature reduces intermixing of tungsten with the layer 208, as depicted in FIG. 2C. As such, selective deposition of tungsten in subsequent operations is improved, so that less tungsten accumulates on the upper surface of the layer 208.

In the PVD system 100 of FIG. 1B, the first power generator 144 generates power at a higher power, such as greater than 4 kW. For example, the power generated by the first power generator 144 may be generated at a level at or above about 8 kW. The higher power level of the first power generator 144 increases ionization rate of tungsten, which improves the bottom thickness T2 of the bottom portion 210B on the feature 220.

In the PVD system 100 of FIG. 1B, the target 102 is separated from the by the distance H1 that is greater than that depicted in the PVD system 100 of FIG. 1A. In some embodiments, the distance H1 is greater than about 100 mm, greater than about 110 mm, greater than about 120 mm, greater than about 130 mm, greater than about 140 mm, or larger. The inventors have realized that the distance H1 being between about 140 mm and about 150 mm is beneficial to improve tungsten ion directionality, which improves the bottom thickness T2 of the bottom portion 210B on the feature 220. In some embodiments, the distance H1 is about 145 mm.

In FIG. 2C, the bottom thickness T2 of the bottom portion 210B may be larger for a smaller value of the selected thickness T1. For example, when the selected thickness T1 is about 50A, the bottom thickness T2 may be about 30A. As such, the contact resistance is reduced due to the bottom thickness T2 being larger, while the width X of the opening 21 is improved (e.g., increased) due to the overhang of the top portion 210T being smaller, which is beneficial to increase process window for subsequent operations.

It should be understood that one or more of the differences just described may be omitted in some embodiments. In some embodiments, one or a combination of generating RF power at the higher level, separating the target 102 from the wafer 118 by the distance H1 greater than about 100 mm and holding the wafer 118 at room temperature is performed when depositing the tungsten thin film 210. For example, when depositing the tungsten thin film 210, the first power generator 144 may generate power at a lower level, such as less than or about 4 kW while the distance H1 may be greater than about 140 mm and the wafer 118 may be at room temperature. In another example, the wafer 118 may be heated to a high temperature, such as about 400 degrees Celsius, while the first power generator 144 generates power at a higher level, such as about 8 kW and the distance H1 is greater than about 140 mm.

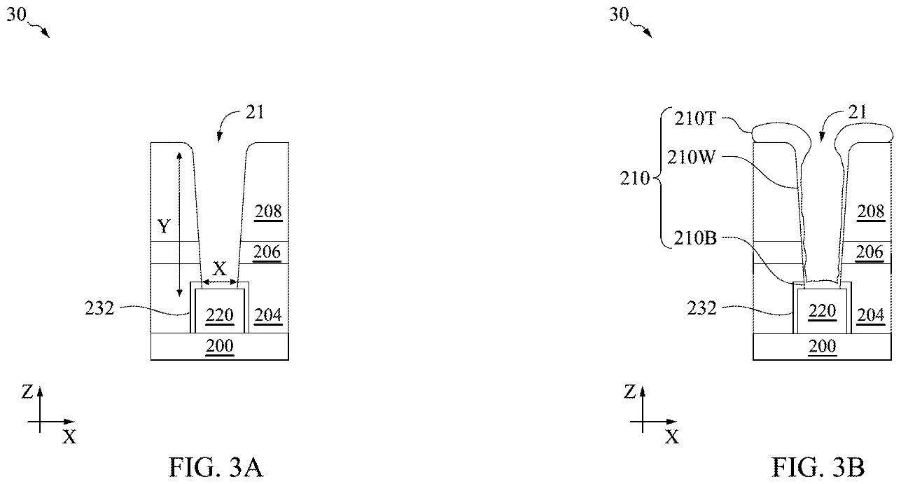

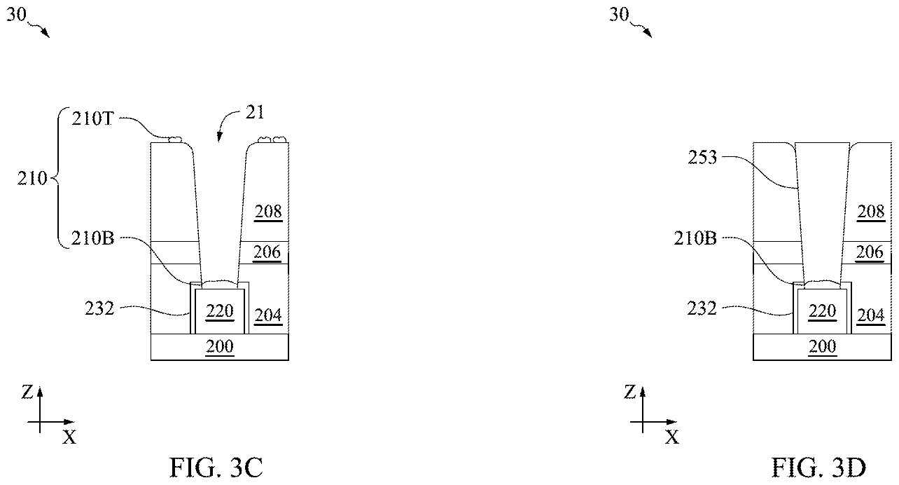

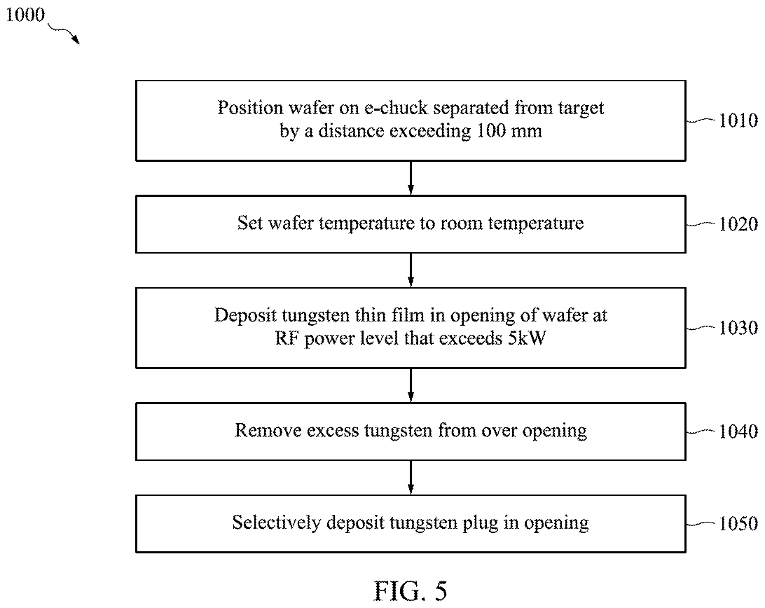

FIGS. 3A-3D are views of various embodiments of an IC device 30 at various stages of fabrication according to various aspects of the present disclosure. The IC device 30 is similar to the IC device 20 of FIG. 2C in many respects and may be an embodiment of the IC device 20 of FIG. 2C. Like reference numerals refer to like elements. FIG. 5 is a flowchart illustrating a method 1000 of fabricating a semiconductor device according to various aspects of the present disclosure. The various stages of fabrication of the IC device illustrated in FIGS. 3A-3D may be performed in accordance with the method of FIG. 5. FIG. 5 illustrates a flowchart of method 1000 for forming an IC device or a portion thereof from a workpiece, according to one or more aspects of the present disclosure. Method 1000 is an example and is not intended to limit the present disclosure to what is explicitly illustrated in method 1000. Additional acts can be provided before, during and after the method 1000 and some acts described can be replaced, eliminated, or moved around for additional embodiments of the methods. Not all acts are described herein in detail for reasons of simplicity. Method 1000 is described below in conjunction with fragmentary perspective and/or cross-sectional views of a workpiece, shown in FIGS. 3A-3D, at different stages of fabrication according to embodiments of method 1000. For avoidance of doubt, throughout the figures, the X direction is perpendicular to the Z direction. It is noted that, because the workpiece may be fabricated into a semiconductor device, the workpiece may be referred to as the semiconductor device as is beneficial to the context.

In FIG. 3A, the IC device 30 is provided. In some embodiments, the IC device 30 includes a feature 220, which may be a gate structure (e.g., a gate metal), a source/drain region, a metal wire or trace, or the like. An upper surface of the feature 220 is exposed by the opening 21, which extends through the first dielectric layer 204, the etch stop layer 206, the second dielectric layer 208 and the barrier layer 232. In some embodiments, width X of the opening 21 may be in a range of about 10 nm to about 40 nm. In some embodiments, height Y of the opening 21 may be in a range of about 20 nm to about 300 nm, about 500 nm to about 1500 nm, or another suitable range.

The IC device 30 may be positioned in or on a wafer, such as the wafer 118. The wafer 118 may be positioned on the electrostatic chuck 128 in the chamber 150, corresponding to act 1010 of method 1000. The wafer 118 having the IC device 30 thereon/therein may be separated from the target 102 by the distance H1 that exceeds 100 mm. For example, the distance H1 may be in the range of about 140 nm to about 150 nm, such as 145 nm.

Following positioning the wafer 118 in the chamber 150 on the electrostatic chuck 128 and prior to depositing the tungsten thin film 210 on the IC device 30 in the opening 21 and on the upper surface of the second dielectric layer 208, temperature of the wafer 118 may be set to room temperature (e.g., 15 degrees Celsius to 30 degrees Celsius) or ambient temperature, corresponding to act 1020 of method 1000. The temperature of the wafer 118 may be set in a variety of manners. In some embodiments, the temperature of the wafer 118 is set by heating or cooling the electrostatic chuck 128 to a temperature in a range of about 15 degrees Celsius to about 30 degrees Celsius. The temperature of the wafer 118 on the electrostatic chuck 128 then approximates that of the electrostatic chuck 128. In some embodiments, the temperature of the wafer 118 is set to room temperature or ambient temperature by disabling heating (e.g., by a heater) of the electrostatic chuck 128, such that temperature of the electrostatic chuck 128 and the wafer 118 is substantially the same as ambient temperature in the chamber 150. It should be understood that “set” includes the meaning of heating, cooling and disabling a heater as just described.

In FIG. 3B, following positioning the wafer 118 in the chamber 150 on the electrostatic chuck 128 and the temperature of the wafer 118 reaching room temperature or ambient temperature, the tungsten thin film 210 is deposited in the opening 21 of the wafer 118 at RF power level that exceeds about 5 kW, corresponding to act 1030 of method 1000. For avoidance of doubt, the wafer 118 is at room temperature or ambient temperature while the tungsten thin film 210 is being deposited. In some embodiments, the RF power level is less than 5 kW, such as about 4 kW.

Due to the wafer 118 being held at room temperature or ambient temperature during the deposition of act 1030, intermixing of tungsten with the second dielectric layer 208 is reduced. Due to the wafer 118 being separated from the target 102 by more than 100 mm, tungsten ion directionality is improved during the deposition of act 1030. Due to the RF power level exceeding 5 KW (e.g., 8 kW), rate of tungsten ionization is increased. As such, the bottom portion 210B of the tungsten thin film 210 is deposited to a thicker thickness T2, which is beneficial for reducing contact resistance with the feature 220. As mentioned previously, one or both of acts 1010 and 1020 may be omitted in some embodiments.

In FIG. 3C, following formation of the tungsten thin film 210, excess material of the tungsten thin film 210, such as the top portion 210T and the sidewall portion 210W, are removed or substantially removed, corresponding to act 1040 of method 1000. As depicted in FIG. 3C, some small portion(s) of the top portion 210T may remain on the upper surface of the second dielectric layer 208 following the removal operation. In some embodiments, the top portion 210T is removed entirely. Removal of the top portion 210T and the sidewall portion 210W may include one or more etching operations, chemical-mechanical planarization (CMP) operations, and the like. For example, a first pullback etch may be performed that may be an isotropic etch, which may be followed by rinsing with water, such as ozonated deionized water. Then, a second pullback etch may be performed that is an isotropic etch using a different etchant than the first pullback etch. A third etch or clean operation may be performed using, for example, dilute hydrofluoric acid. Other suitable etchants and/or cleaning agents may be used for the first pullback etch, the second pullback etch and the third etch or clean in some embodiments. In some embodiments, the bottom portion 210B has slightly reduced thickness T2 following the removal operation of act 1040.

In FIG. 3D, following removal of the excess material of the tungsten thin film 210 in act 1040, a tungsten plug 253 is selectively formed in the opening 21, corresponding to act 1050 of method 1000. The tungsten plug 253 may be formed on the bottom portion 210B that remains in the opening 21 on the upper surface of the feature 220. Formation of the tungsten plug 253 may include one or more deposition operations that selectively deposit tungsten on the bottom portion 210B without substantially depositing tungsten on other surfaces of the IC device 30. In some embodiments, selective deposition of tungsten on the bottom portion 210B includes a chemical vapor deposition (CVD), which may be an atomic layer deposition (ALD), that uses the bottom portion 210B as a seed layer for selective deposition of tungsten.

In one example, the thin layer of tungsten that is the bottom portion 210B may act as a nucleation layer in the selective deposition process using ALD. The tungsten nucleation layer serves as a seed layer for subsequent tungsten deposition and can promote adhesion and enhance the selective deposition process. The ALD process may involve multiple steps. For example, multiple ALD cycles may be performed with the bottom portion 210B acting as the seed layer for further tungsten growth. A tungsten precursor pulse may be performed, in which a tungsten precursor gas is introduced as a pulse that reacts with the bottom portion 210B to form a monolayer of tungsten. Then, a purge operation may be performed in which the chamber 150 is purged to remove excess or unreacted precursor and byproducts. A selective agent pulse may be performed, in which a reducing agent or plasma treatment is applied to remove any unreacted precursor or tungsten compounds from non-nucleation sites. Then, another purge step may be performed to remove remaining gases and byproducts. The ALD cycles may be repeated to deposit the desired thickness of tungsten selectively on the bottom portion 210B, avoiding deposition on non-nucleation areas, such as the upper surface of the second dielectric layer 208.

Due to the tungsten plug 253 being formed by CVD or ALD and the bottom portion 210B being formed by PVD, a discernable interface may be present between the tungsten plug 253 and the bottom portion 210B. For example, grain size of the bottom portion 210B may be larger than grain size of the tungsten plug 253.

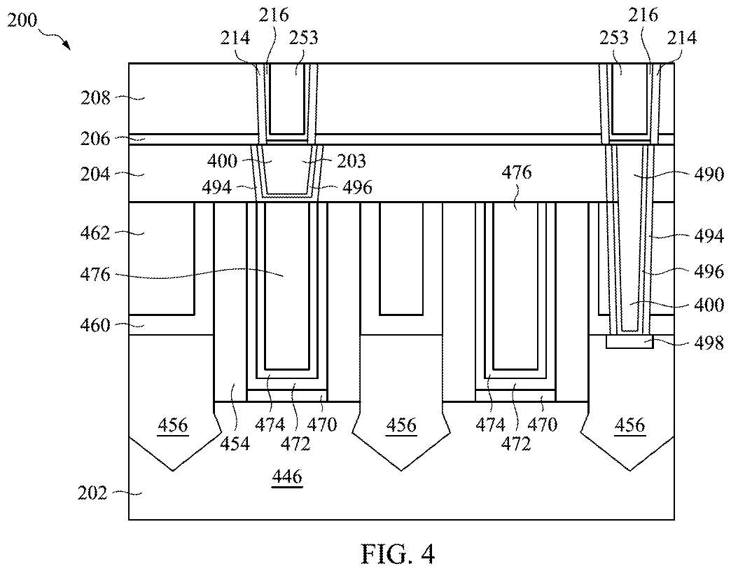

FIG. 4 depicts an example of a location in the semiconductor device where a conductive fill material 253 formed by the process of FIGS. 3A-3D may be utilized. The conductive fill material 253 may be the tungsten plug 253 of FIG. 3D, in some embodiments. In the example depicted in FIG. 4, the conductive fill material 253 may be utilized to connect with underlying conductive features 203, wherein the underlying conductive features 203 are utilized as contact plugs in a contact structure. A first dielectric layer 204 is utilized as an interlayer dielectric (ILD) having the contact plugs (e.g., the conductive features 203) formed therein.

The substrate 202 includes fin structures 446 formed on the upper portion of the substrate 202. Epitaxy source/drain regions 456 are formed in the fin structure 446. Gate structures are formed on the fin structure 446. Each gate structure includes an interfacial dielectric 470, a gate dielectric layer 472, one or more optional conformal layers 474, and a gate electrode 476. Gate spacers 454 are formed along sidewalls of the gate structures. The interfacial dielectric 470 is along surfaces of the fin structure 446 between respective gate spacers 454. The gate dielectric layer 472 is conformally on the interfacial dielectric 470 and along sidewalls of and between respective gate spacers 454. The one or more optional conformal layers 474 are conformally on the gate dielectric layer and can include one or more barrier and/or capping layers and one or more work-function tuning layers. The gate electrodes 476 are on the one or more optional conformal layers 474.

A contact etch stop layer (CESL) 460 is conformally on surfaces of the epitaxy source/drain regions 456, and sidewalls of gate spacers 454. A first interlayer dielectric (ILD) 462 is over the CESL 460. The first dielectric layer 204 is formed over the first ILD 462, CESL 460, gate spacers 454, and gate structures. Conductive features 203, 490 are formed to electrically connect to the gate structure and the epitaxy source/drain region 456, respectively. The conductive feature 490 includes, in the illustrated example, an adhesion layer 494, a barrier layer 496 on the adhesion layer 494, a silicide region 498 on the epitaxy source/drain region 456 and conductive fill material 400 on the barrier layer 496, for example. The conductive feature 203 includes, in the illustrated example, an adhesion layer 494, a barrier layer 496 on the adhesion layer 494 and conductive fill material 400 on the barrier layer 496, for example. The tungsten plug 253 may be formed on one or more of the conductive feature 203, the conductive feature 490 and the gate electrode 476.

An etch stop layer 206 is on the first dielectric layer 204 and the conductive features 490, 203. A second dielectric layer 208 is on the etch stop layer 206. Conductive features (including the barrier layer 214, the liner layer 216 on the barrier layer 214, and the conductive fill material 253 on the liner layer 216) are formed through the second dielectric layer 208 and the etch stop layer 206 and electrically connected to the conductive features 203, 490.

Embodiments may provide advantages. Due to the wafer 118 being held at room temperature or ambient temperature during deposition of the tungsten thin film 210, intermixing of tungsten with the second dielectric layer 208 is reduced, which is beneficial to selective deposition that forms the tungsten plug 253 in a subsequent operation. Due to the wafer 118 being separated from the target 102 by more than 100 mm, tungsten ion directionality is improved during the deposition and due to the RF power level exceeding 5 KW (e.g., 8 kW), rate of tungsten ionization is increased. As such, the bottom portion 210B of the tungsten thin film 210 is deposited to a thicker thickness T2, which is beneficial for reducing contact resistance with the feature 220. Improved selective deposition and reduced contact resistance are beneficial to improve WAT and/or yield of the IC device 30 including the tungsten plug 253.

In accordance with at least one embodiment, a method includes: positioning a wafer on a wafer support of a physical vapor deposition apparatus, the wafer being separated from a target by a distance exceeding 100 millimeters, the wafer including an opening exposing a conductive feature; setting a temperature of the wafer to a room temperature; forming a tungsten thin film in the opening by the physical vapor deposition apparatus using a radio frequency power level that exceeds about 5 kilowatts, the tungsten thin film including a bottom portion that is on an upper surface of the conductive feature exposed by the opening; removing excess tungsten of the tungsten thin film from over the opening; and forming a tungsten plug in the opening on the bottom portion by selectively depositing tungsten by a chemical vapor deposition operation.

In accordance with at least one embodiment, a method includes: positioning a wafer on an electrostatic chuck of a physical vapor deposition apparatus, the wafer including an opening exposing a conductive feature; setting a temperature of the wafer to a room temperature; forming a tungsten thin film in the opening by the physical vapor deposition apparatus, the tungsten thin film including a bottom portion that is on an upper surface of the conductive feature exposed by the opening, a top portion that is on an upper surface of a dielectric layer through which the opening extends and a sidewall portion that is on a sidewall of the dielectric layer exposed by the opening; removing the top portion and the sidewall portion of the tungsten thin film from over the opening; and forming a tungsten plug in the opening on the bottom portion by selectively depositing tungsten by a chemical vapor deposition operation.

In accordance with at least one embodiment, an apparatus includes: a chamber; a physical vapor deposition target positioned in an upper portion of the chamber; and a wafer support in a lower portion of the chamber, wherein in operation, the wafer support is separated from the target by a distance in a range of about 140 millimeters to about 150 millimeters during deposition of ions of the physical vapor deposition target onto a wafer positioned on the wafer support.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
positioning a wafer on a wafer support of a physical vapor deposition apparatus, the wafer being separated from a target by a distance exceeding 100 millimeters, the wafer including an opening exposing a conductive feature;
setting a temperature of the wafer to a room temperature;
forming a tungsten thin film in the opening by the physical vapor deposition apparatus using a radio frequency power level that exceeds about 5 kilowatts, the tungsten thin film including a bottom portion that is on an upper surface of the conductive feature exposed by the opening;
removing excess tungsten of the tungsten thin film from over the opening; and
forming a tungsten plug in the opening on the bottom portion by selectively depositing tungsten by a chemical vapor deposition operation.

2. The method of claim 1, wherein the wafer is separated from the target by a distance in a range of about 140 millimeters to about 150 millimeters.

3. The method of claim 1, wherein the radio frequency power level exceeds about 8 kilowatts.

4. The method of claim 1, wherein the setting a temperature of the wafer is setting the temperature of the wafer to a temperature in a range of about 15 degrees Celsius to about 30 degrees Celsius.

5. The method of claim 4, wherein the forming a tungsten thin film includes maintaining the temperature of the wafer within the range while the tungsten thin film is being deposited.

6. The method of claim 1, wherein the forming a tungsten thin film includes forming the bottom portion, forming a top portion on an upper surface of a dielectric layer through which the opening extends and forming a sidewall portion on a sidewall of the dielectric layer exposed by the opening.

7. The method of claim 6, wherein the removing excess tungsten includes removing the top portion and the sidewall portion.

8. A method, comprising:
positioning a wafer on an electrostatic chuck of a physical vapor deposition apparatus, the wafer including an opening exposing a conductive feature;
setting a temperature of the wafer to a room temperature;
forming a tungsten thin film in the opening by the physical vapor deposition apparatus, the tungsten thin film including a bottom portion that is on an upper surface of the conductive feature exposed by the opening, a top portion that is on an upper surface of a dielectric layer through which the opening extends and a sidewall portion that is on a sidewall of the dielectric layer exposed by the opening;
removing the top portion and the sidewall portion of the tungsten thin film from over the opening; and
forming a tungsten plug in the opening on the bottom portion by selectively depositing tungsten by a chemical vapor deposition operation.

9. The method of claim 8, wherein the setting a temperature includes heating the electrostatic chuck to a temperature in a range of about 15 degrees Celsius to about 30 degrees Celsius.

10. The method of claim 8, wherein the setting a temperature includes disabling a heater of the electric chuck.

11. The method of claim 10, wherein the heater is disabled throughout the forming a tungsten thin film.

12. The method of claim 10, wherein the forming a tungsten plug includes forming the tungsten plug having a different grain size than that of the bottom portion.

13. The method of claim 10, wherein the forming a tungsten plug includes forming the tungsten plug having a smaller grain size than that of the bottom portion.

14. The method of claim 10, wherein the forming a tungsten plug includes forming the tungsten plug such that a discernable interface is present between the tungsten plug and the bottom portion.

15. An apparatus, comprising:
a chamber;
a physical vapor deposition target positioned in an upper portion of the chamber; and
a wafer support in a lower portion of the chamber, wherein in operation, the wafer support is separated from the target by a distance in a range of about 140 millimeters to about 150 millimeters during deposition of ions of the physical vapor deposition target onto a wafer positioned on the wafer support.

16. The apparatus of claim 15, further comprising a power supply electrically connected to the physical vapor deposition target, the power supply, in operation, supplying radio frequency power at a level that exceeds about 8 kilowatts during the deposition of ions.

17. The apparatus of claim 15, wherein, in operation, the deposition of ions is onto the wafer that is at room temperature.

18. The method of claim 15, wherein the wafer support includes an electrostatic chuck that has a heater.

19. The method of claim 18, wherein the heater, in operation, is disabled during the deposition of ions.

20. The method of claim 18, wherein the heater, in operation, heats the wafer to about room temperature during the deposition of ions.
